(19) United States
(12) Patent Application Publication
(10) Pub. No.: US 2025/0138941 A1
(43) Pub. Date: May 1, 2025

(54) SEMICONDUCTOR DEVICE, READING METHOD AND PROGRAM

(71) Applicant: Renesas Electronics Corporation, Tokyo (JP)

(72) Inventors: Akira HAMAGUCHI, Tokyo (JP); Yuji KUBO, Tokyo (JP)

(21) Appl. No.: 18/915,557

(22) Filed: Oct. 15, 2024

(30) Foreign Application Priority Data
Oct. 25, 2023 (JP) 2023-183399

(51) Int. Cl. G06F 11/10

(52) U.S. Cl. CPC G06F 11/1016; G06F 11/1068

(57) ABSTRACT

A semiconductor device includes a non-volatile memory (NVM) capable of data-writing even after the semiconductor device is shipped. When a read request is made, the semiconductor reads and outputs the content stored in the area of the NVM in place of the replacement target data in the instruction codes stored in a read only memory. Therefore, after shipping of the semiconductor device, even if a defect such as fragility in the code used at the start of the semiconductor device is found, replacement data in place of 10 the data to be replaced it can be obtained. That is, the semiconductor device, replacement process using the modified patches of Boot ROM cord is enabled.

### CROSS-REFERENCE TO RELATED APPLICATIONS

The disclosure of Japanese Patent Application No. 2023-183399 filed on Oct. 25, 2023, including the specification, drawings and abstract is incorporated herein by reference in its entirety.

### BACKGROUND

The present disclosure relates to semiconductor devices, methods and programs, and, for example, to semiconductor devices, methods and programs that allow replacement of data stored in a ROM.

There are disclosed techniques listed below.

### [Patent Document 1] Japanese Unexamined Patent Application Publication 2002-149431

Patent Document 1, by storing the patch load program, provided with a patch load ROM (Read Only Memory) selected by the activation selection signal from the activation selection circuit, a microcomputer that allows patch correction is disclosed.

### SUMMARY

Not limited to the microcomputer disclosed in Patent Document 1, in semiconductor device, it is required to be able to replace the data stored in ROM.

Other objects and novel features will become apparent from the description of this specification and the accompanying drawings.

A semiconductor device according to one aspect of the present disclosure includes a read only memory (ROM) in which data is stored, a non-volatile memory (NVM) in which replacement data of at least a portion of the data is stored, and a controller that performs either reading the data from the ROM or reading the replacement data from the non-volatile memory in response to a request to read the data from a processor.

A reading method according to an aspect of the present disclosure, the semiconductor device receives a read request of data stored in a ROM, and either reads the data from the ROM or reads the replacement data from an NVM in which replacement data of at least a part of the data is stored, in response to the read request.

A program according to one aspect of the present disclosure accepts a request to read data stored in a ROM and, in response to the read request, executes either reading the data from the ROM or reading the replacement data from a non-volatile memory in which replacement data of at least a portion of the data is stored.

The present disclosure can provide semiconductor device, method and program that allow replacement of data stored in a ROM.

### BRIEF DESCRIPTION OF THE DRAWINGS

FIG. 1 is a block diagram showing a configuration example of a semiconductor device which has been studied in advance.

FIG. 2 is a block diagram showing a configuration example of a semiconductor device according to a first embodiment.

FIG. 3A is a flowchart showing an example of a typical process of the semiconductor device according to the first embodiment.

FIG. 3B is a flowchart showing an example of a typical process of the semiconductor device according to the first embodiment.

FIG. 4 is a block diagram showing a configuration example of a semiconductor device according to a second embodiment.

FIG. 5A is a flowchart showing an example of a typical process of the semiconductor device according to the second embodiment.

FIG. 5B is a flowchart showing an example of a typical process of the semiconductor device according to the second embodiment.

FIG. 5C is a flowchart showing an example of a typical process of the semiconductor device according to the second embodiment.

FIG. 5D is a flowchart showing an example of a typical process of the semiconductor device according to the second embodiment.

### DETAILED DESCRIPTION

Hereinafter, an embodiment will be described with reference to the drawings. Since the drawings are simplified, the technical scope of the embodiment should not be narrowly interpreted based on the description of the drawings. Further, the same elements are denoted by the same reference numerals, without redundant description.

In the following embodiments, where it is necessary for convenience, it will be described by dividing it into multiple sections or embodiments. However, unless otherwise specified, they are not mutually related, one is in the relationship of some or all modifications of the other, examples of application, detailed description, supplemental explanation, etc. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle.

Furthermore, in the following embodiments, the constituent elements (including the operation steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above-mentioned numbers and the like, including the number, the numerical value, the amount, the range, and the like.

The configuration or process shown in the embodiments may be appropriately combined with the configuration or process shown in other embodiments.

### Preliminary Study by the Inventors

Before describing the semiconductor device according to the present embodiment, the present inventors will be described a semiconductor device which has been studied in advance.

Recently, the technique of connected and ADAS (Advanced Driver Assistance Systems) has been developed in the automotive field. With the development of such technology, many in-vehicle electronic devices such as in-vehicle cameras, drive recorders, and car navigation systems have been installed in vehicles and connected to a network. Here, when the in-vehicle electronic device is connected to the network, the risk that the in-vehicle electronic device is exposed to the cyber-attack from the cracker or the like increases. Therefore, it is more important to improve the security of the semiconductor device to be mounted on the in-vehicle electronic device.

Generally, among the codes stored in a semiconductor device, the codes for which vulnerabilities are discovered are updated by techniques such as OTA (Over The Air), and countermeasures for vulnerabilities are implemented. However, there is a problem that it is difficult to modify such code if there is a vulnerability etc. in the code in the memory that cannot be changed after shipment such as ROM.

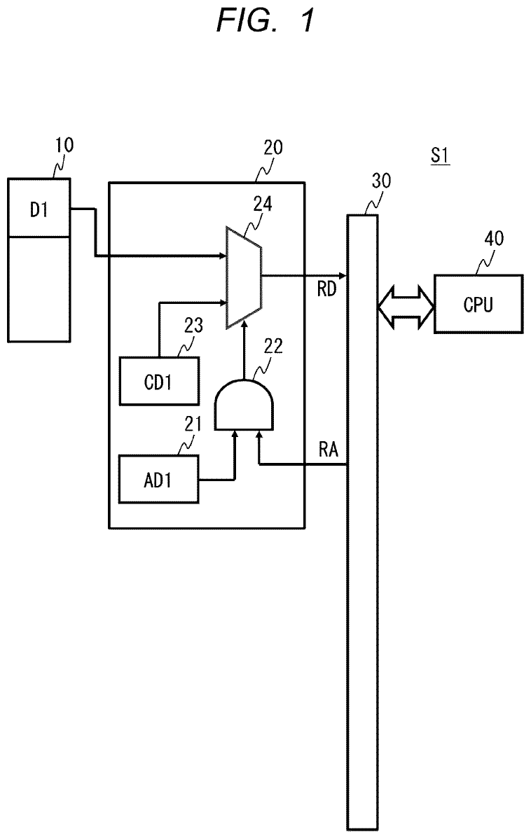

FIG. 1 is a block diagram showing a configuration example of a semiconductor device S1 that has been studied in advance with the purpose of solving such a problem. The semiconductor device S1 comprises a ROM 10, a ROM controller 20, a bus 30 and a CPU (Central Processing Unit) 40.

The ROM 10 contains instruction codes D1 executed by the CPU 40. The instruction codes D1 stored in the ROM 10 cannot be overwritten or modified. The ROM 10 are connected to the input terminals of a multiplexer 24 of the ROM controller 20. When receiving a command such as the CPU 40, the ROM 10 outputs the data on the ROM 10 corresponding to the address requested by the command to the ROM controller 20.

The ROM controller 20 includes address storage registers 21, an AND circuit 22, code storage registers 23 and the multiplexer 24. The address storage registers 21 store an information of an address AD1 in which the code to be replaced is stored in the instruction codes D1 among the storage addresses of the ROM 10. The AND circuit 22 receives a read address RA output from the CPU 40 through the bus 30 and the address AD1 output from the address storage registers 21. The AND circuit 22 outputs “1” as an output value when inputted read address RA and the address AD1 coincide, and outputs “0” as an output value when not coincide.

The code storage registers 23 contain replacement codes CD1 that are used as alternative to codes to be replaced in the instruction codes D1. The replacement codes CD1 are the replacement data of part or all of the instruction codes D1. The multiplexer 24 receives the instruction codes D1 output from the ROM 10 and the replacement codes CD1 output from the address storage registers 21. Further, the output value of the AND circuit 22 is inputted to the multiplexer 24 as a selection signal. The multiplexer 24 outputs the instruction codes D1 as read data RD when the select signal is “0”. On the other hand, the multiplexer 24 outputs the replacement codes CD1 as the read data RD when the selection signal is “1”.

The bus 30 connects the ROM controller 20 and the CPU 40. When the CPU 40 executes a read for a predetermined storage address of the instruction codes D1, it outputs the information of the storage address to be read as a read address RA. The CPU 40 acquires a read data RD output from the ROM controller 20 through the bus 30 as a result of outputting the read address RA.

After shipping the semiconductor device S1, a vulnerability problem is discovered in the instruction codes D1 of the ROM 10 and some of them may need to be replaced. At this time, after activation of the semiconductor device S1, the replacement codes CD1 to be replaced is written to the code storage registers 23, and the address AD1 of the replacement codes CD1 is written to the address storage registers 21. This operation changes the read destination of the ROM controller 20 from the ROM 10 to the code storage registers 23 when the CPU 40 reads the address AD1. Therefore, the CPU 40 reads the replacement codes CD1 for the address AD1. Therefore, it is possible to solve the problem of the vulnerability.

However, in the technique shown in FIG. 1, there are the following problems.
(1) After starting the semiconductor device S1 once, the semiconductor device S1 needs to perform writing in the address storage registers 21 and the code storage registers 23. Therefore, the semiconductor device S1 cannot replace the code that is read at the CPU 40 at startup.

As a general security measure, it is conceivable to introduce the function of the secure boot that checks the accuracy of software executed on the semiconductor device before executing the software into the semiconductor device. The functions of the secure boot are executed by codes on a ROM pre-mounted n the semiconductor device (hereinafter also referred to as boot ROM codes). However, in the technique shown in FIG. 1, when the need to replace part of the boot ROM cords occurs, it is considered difficult to implement the replacement.

Further, the technique shown in FIG. 1 also causes the following problems.
(2) Generally, the register area is small, so the amount of data that can be stored in the code storage registers 23 is small. Therefore, the code size to be replaceable in the instruction codes D1 is reduced.

The semiconductor device shown in the following embodiments, it is possible to solve the problems described above.

### First Embodiment

### (Configuration Description)

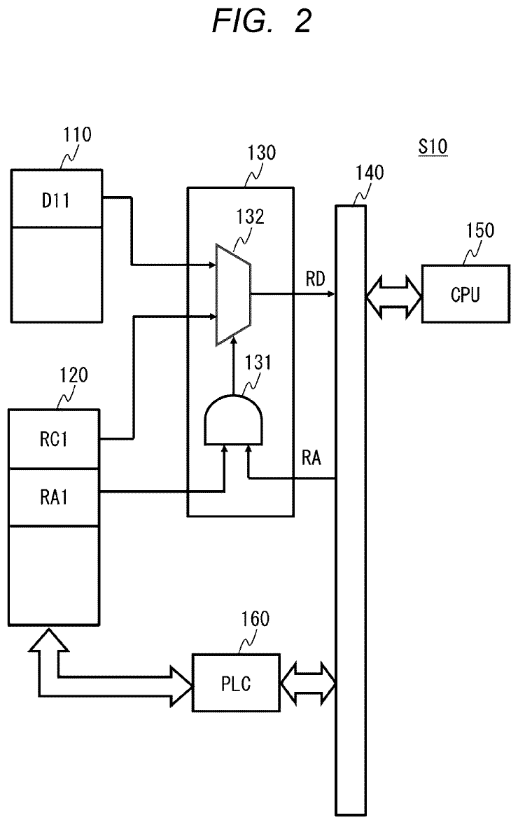

FIG. 2 is a block diagram showing a configuration example of a semiconductor device S10 according to the first embodiment. The device S10 includes a ROM 110, an NVM 120, a ROM controller 130, a bus 140, a CPU 150, and a PLC (Programmable Logic Controller) 160.

The ROM 110 contains instruction codes D11 executed by the CPU 150. The instruction codes D11 stored in the ROM 110 cannot be overwritten or modified. For example, the instruction codes D11 may be boot ROM codes. When receiving commands from the CPU 150, the ROM 110 outputs the data on the ROM 110 corresponding to the address requested by the command to the ROM controller 130. Hereinafter, an area in which the instruction codes D11 are stored is also described as an area D11. The area D11 of the ROM 110 is connected to a first input terminal of a multiplexer 132.

The NVM 120 is a nonvolatile memory that retains state even when power is not supplied. The NVM 120 stores replacement codes RC1 that are used as an alternative to the code to be replaced in the instruction codes D11. The replacement codes RC1 are the replacement data of part or all of the instruction codes D11. Further, the NVM 120 stores the information (first address information) of the replacement address RA1 as an address of the storage address of the ROM 110 in which the code to be replaced is stored in the instruction codes D11.

Hereinafter, the area in which the replacement codes RC1 are stored is described as the area RC1, and the area in which the replacement address RA1 is stored is also described as the area RA1. The area RC1 and the area RA1 are also collectively referred to as patch areas. The area RC1 of the NVM 120 is connected to a second input terminal of the multiplexer 132 and the area RA1 is connected to the first input terminal of an AND circuit 131.

The semiconductor device S10 can rewrite the data stored in the NVM 120 using the PLC 160 after the manufacturing. For example, the NVM 120 may be a once-rewritable OTP (One Time Programmable) memory. However, a specific embodiment of the NVM 120 is not limited thereto.

The ROM controller 130 comprise circuits with the AND circuit 131 and the multiplexer 132. The first input terminal of the AND circuit 131 is connected to the area RA1, and the second input terminal of the AND circuit 131 is connected to the bus 140. Therefore, the read address RA outputted from the CPU 150 through the bus 140 and the replacement address RA1 read from the area RA1 are input to the AND circuit 131. The AND circuit 131 outputs “1” as an output value when the input read address RA and the replacement address RA1 coincide, and outputs “0” as an output value when not coincide.

The area D11 is connected to the first input terminal of the multiplexer 132, and the area RC1 is connected to the second input terminal of the multiplexer 132. Therefore, instruction codes D11 output from the ROM 110 and replacement codes RC1 output from the NVM 120 are input to the multiplexer 132. Further, the multiplexer 132, the output of the AND circuit 131 are inputted as a selection signal. The multiplexer 132 outputs the instruction codes D11 as the read data RD when the select signal is “0”. On the other hand, the multiplexer 132 outputs the replacement codes RC1 as the read data RD when the selection signal is “1”.

The bus 140 connects the ROM controller 130, the CPU 150 and the PLC 160 to each other. When the CPU 150 executes a read for a predetermined storage address of the ROM 110, it outputs the information of the storage address to be read as the read address RA. Then, the CPU 150 outputs the read address RA to acquire the read data RD output from the ROM controller 130 through the bus 140.

The PLC 160 is a write sequencer that rewrites any data stored in the NVM 120 when it receives a command such as the CPU150.

### (Description of the Process Flow)

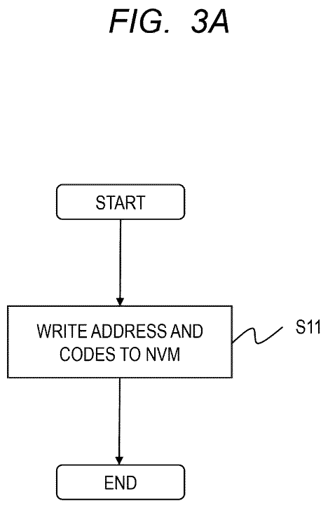

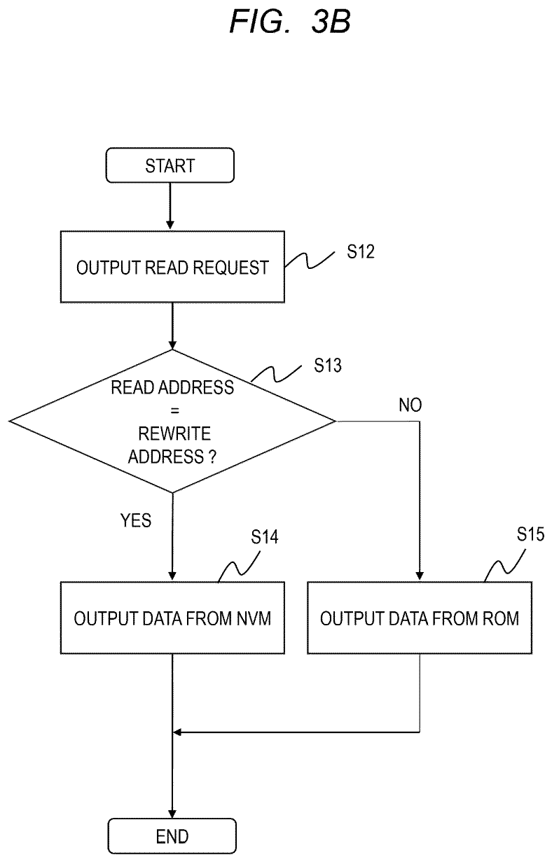

FIGS. 3A and 3B are flow charts showing process examples of a semiconductor device S10, and referring to these flow charts, an outline of the process of the semiconductor device S10 will be described. Incidentally, for the portion already described for each process, the description thereof is omitted as appropriate.

First, as shown in FIG. 3A, the PLC 160 writes the replacement address RA1 into the area RA1 of the NVM 120. The PLC 160 also writes the replacement codes RC1 used as an alternative to the code to be replaced into the area RC1 of the NVM 120 (in step S11). The PLC 160, for example, at the time of shipping or after shipping of the semiconductor device S10, in response to the command of the CPU 150, it executes the process of the correction operation described in the step S11.

Next, after step S11, the process performed after the activation of the semiconductor device S10 will be described with reference to FIG. 3B. When reading the data of the ROM 110, the CPU 150 outputs the information of the address to be read to the bus 140 as a read address RA, and outputs a read request to the ROM controller 130 (in step S12).

The ROM controller 130 change the operation according to whether or not the read address RA for which a read request has been made matches the replacement address RA1 (in step S13). If the read address RA matches the replace address RA1 (“Yes” in step S13), the ROM controller 130 read from the area RC1 of the NVM 120 rather than from the ROM 110. The ROM controller 130 outputs the read replacement codes RC1 as a read data RD to the bus 140 (in step S14).

On the other hand, if the read address RA does not correspond to the replace address RA1 (in “No” of step S13), the ROM controller 130 read the data from the ROM 110. The ROM controller 130 outputs the read instruction codes D11 as a read data RD to the bus 140 (in step S15).

As described above, the semiconductor device S10 includes the NVM 120 capable of data-writing even after the semiconductor device is shipped. When a read request is made, the ROM controller 130 read and output the content stored in the area RC1 of the NVM 120 in place of the replacement target data in the instruction codes D11 stored in the ROM 110. Therefore, after shipping of the semiconductor device S10, even if a defect such as fragility in the code used at the start of the semiconductor device S10 is found, the CPU 150, replacement data in place of the data to be replaced it can be obtained. That is, the semiconductor device S10, replacement process using the modified patches of Boot ROM cord is enabled, it is possible to solve the problems of (1).

### (Description of the Variation)

In the first embodiment, the PLC 160 can also perform the following processes. For the PLC 160, the CPU 150 or the like, either the normal mode from the outside of the PLC 160 (a first mode) or special mode for testing (a second mode) may be specified.

When the normal mode is specified, the PLC 160 does not perform an operation of writing the information of the replacement address RA1 or the replacement codes RC1 or the information of the replacement address RA1 and the replacement codes RC1 to the patched area of the NVM 120. In the normal mode, even if the command of writing to the patch area is sent to the PLC 160, the command is not executed and becomes invalid.

On the other hand, when the special mode is specified, the PLC 160 performs an operation of writing the information of the replacement address RA1 or the replacement codes RC1 or the information of the replacement address RA1 and the replacement codes RC1 to the patched area of the NVM 120. A special mode is specified, for example, when a vulnerability is discovered in the semiconductor device S10, and the CPU 150 performs the writing of the replacement data.

In the variations shown above, the normal mode limits writing to the patch area. Therefore, even though there is no need to write to the patch area, it is possible to suppress the situation in which the instruction code is illegally replaced by writing to the patch area. In other words, it is possible to suppress the misuse of the write function to the patch area.

### Second Embodiment

### (Configuration Description)

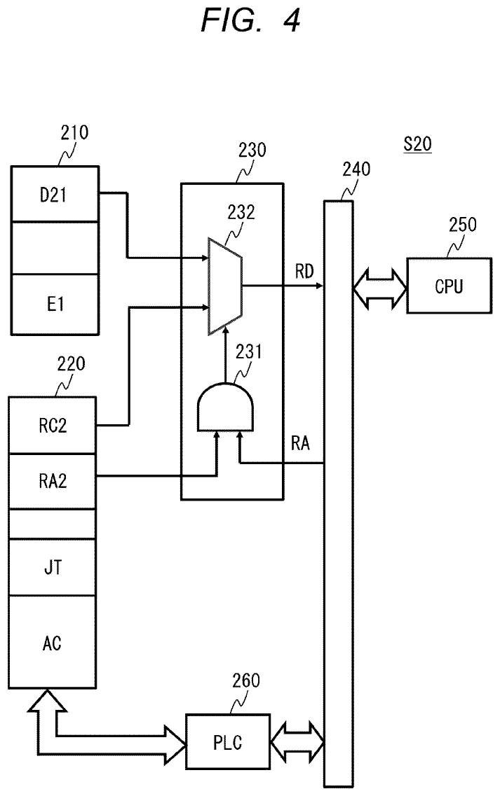

FIG. 4 is a block diagram showing a configuration example of a semiconductor device S20 according to a second embodiment. The semiconductor device S20 includes a ROM 210, an NVM 220, a ROM controller 230, a bus 240, a CPU 250, and a PLC 260. In the description of the following semiconductor device S20, points previously described in the description of the semiconductor device S10, the description is omitted as appropriate.

The ROM 210 stores instruction codes D21 executed by the CPU 250 and an entry table E1 (first jump destination information) used to jump the CPU 250 to an additional coding area on the NVM 220. For example, the instruction codes D21 may be boot ROM codes, but is not limited. The entry table El contains codes for the CPU 250 to read out. When the CPU 250 reads the codes, the CPU 250 reads the address indicated in the jump destination table JT (second address information) stored in the NVM 220 and jumps to the read address. When receiving a command from such as the CPU 250, the

ROM 210 outputs the data on the ROM 210 corresponding to the address requested by the command to the ROM controller 230. Hereinafter, an area in which the instruction codes D21 are stored is also described as an area D21. The area D21 of the ROM 210 is connected to a first input terminal of a multiplexer 232.

The NVM 220 is a non-volatile memory that retains storage even when power is not supplied. The NVM 220 stores replacement codes RC2 that is used as an alternative to the code to be replaced in the instruction codes D21. The replacement codes RC2 is the codes (second jump destination information) of the relative jump instruction to the entry table E1 stored in the ROM 210. Further, the NVM 220 stores the information (a first address information) of the replacement address RA2 as an address of the storage address of the ROM 210 in which the code to be replaced is stored in the instruction codes D21 read by the CPU 250. Hereinafter, the area in which the replacement codes RC2 are stored is described as the area RC2, and the area in which the replacement address RA2 is stored is also described as the area RA2. The area RC2 and the area RA2 are also collectively described as patched areas (second areas). The area RC2 of the NVM 120 is connected to a second input terminal of the multiplexer 132 and the area RA2 is connected to the first input terminal of an AND circuit 131.

In addition, the NVM 220 stores additional codes AC to be executed in place of the code to be replaced in the instruction codes D21 when the instruction codes D21 are executed. The additional codes AC is the permutation of part or all of the instruction codes D21. In the NVM 220, the entry address of the additional code AC is stored in the jump destination table JT. Hereinafter, the area JT of the NVM 220 in which the jump destination table JT is stored, and the area in the NVM 220 in which the additional codes AC are stored is also described as the area AC. The area JT and the area AC are also collectively referred to as additional coding areas (a first area).

The semiconductor device S20 can rewrite the data stored in the NVM 220 using the PLC 260 after the manufacturing. For example, the NVM 220 may be OTP memory, but the embodiment of the NVM 220 is not limited thereto.

The ROM controller 230 comprises circuits with the AND circuit 231 and the multiplexer 232. Since the configuration and operation of the AND circuit 231 and the multiplexer 232 are similar to those of the AND circuit 131 and the multiplexer 132 shown in the first embodiment, a detailed description thereof will be omitted.

Since the configuration and operation of the bus 240, the CPU 250, and the PLC 260 are the same as those of the bus 140, the CPU 150, and the PLC 160 shown in the first embodiment, a detailed description thereof will be omitted.

### (Description of the Process Flow)

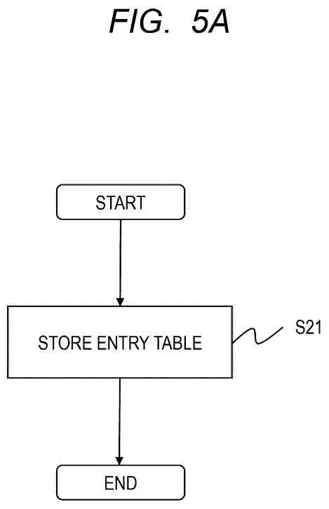

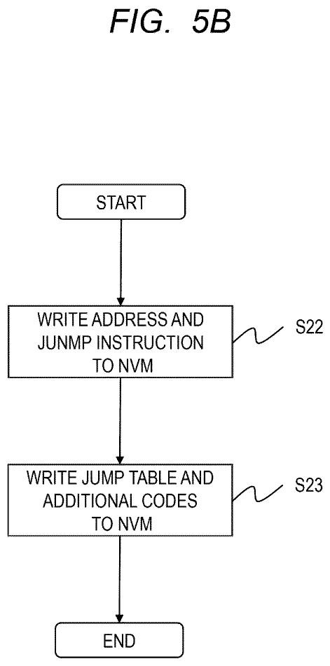

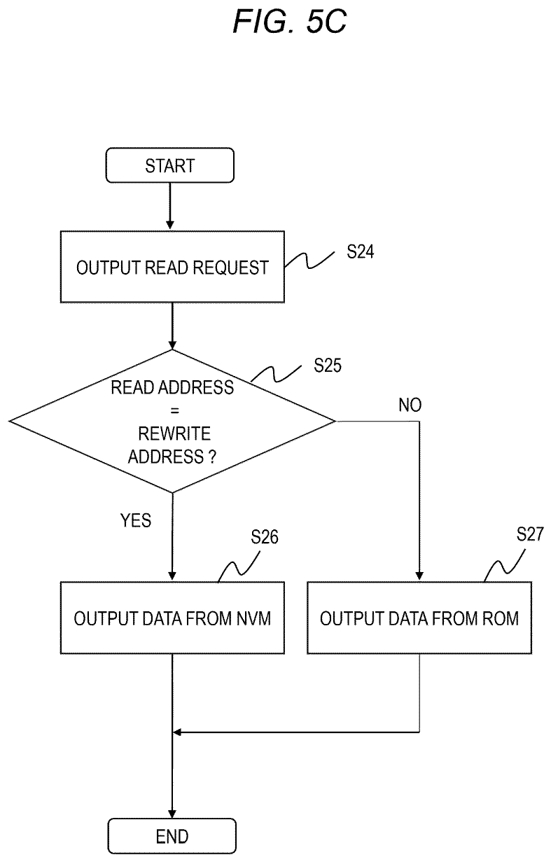

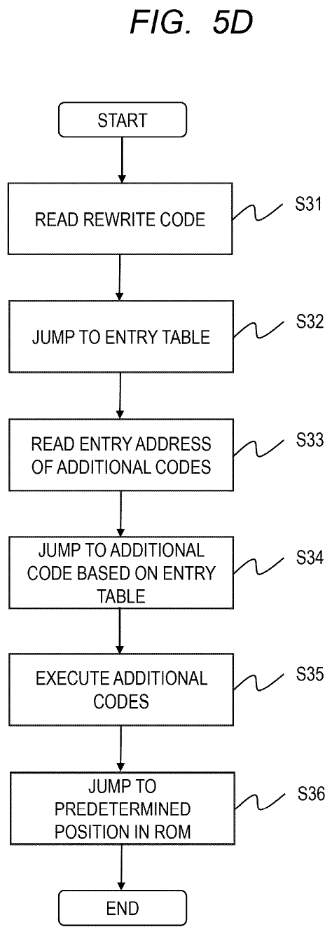

FIGS. 5A to 5D are flow charts showing an exemplary process of a semiconductor device S20, and an outline of the process of the semiconductor device S20 will be described with reference to these flow charts. Incidentally, for the portion already described for each process, the description thereof is omitted as appropriate.

First, as shown in FIG. 5A, at the manufacturing stage of the semiconductor device S20, the entry table E1 is stored in the ROM 210 (in step S21).

The process done after the stepping S11 will now be described with reference to FIG. 5B. The PLC 260 writes the replacement address RA2 to the area RA2 of the NVM 220. The PLC 260 also writes the codes of the relative jump instruction into the area RC2 of the NVM 220 as replacement codes RC2 (in step S22).

The PLC 260 writes the additional code AC into the area AC by writing the jump destination table JT including the entry address of the additional codes AC into the area JT (in step S23). At this time, the PLC 260 writes a return command to the area AC so that the CPU 250 jumps to a predetermined position on the ROM 210 after the additional codes AC have been read, and the data of the jump destination is read. The predetermined position may be, for example, the following instruction of the code replaced by the replacement codes RC2 in the instruction codes D21. Alternatively, the predetermined position may be a suffix of a functional of the code replaced by the replacement codes RC2. The PLC 260, for example at the time of shipping or after shipping of the semiconductor device S20, in response to the CPU 250 instruction, it executes the process of the correction operation described in steps S22 and S23.

Next, after step S23, the process performed after the activation of the semiconductor device S10 will be described with reference to FIGS. 5C and 5D. The CPU 250 outputs a read request to the ROM controller 230 (in step S24). This detail is similar to step S12.

The ROM controller 230 changes the operation according to whether or not the read address RA for which a read request has been made matches the replacement address RA2 (in step S25). If the read address RA matches the replacement address RA2 (“Yes” in step S25), the ROM controllers 230 reads the replacement codes RC2 from the area RC2 instead of reading the instruction codes D21 from the ROM 210. The ROM controller 230 outputs the replacement codes RC2 as a read data RD to the bus 240 (in step S26). This detail is similar to steps S13 and S14.

On the other hand, when the read address RA does not match the replacement address RA2 (“No” in step S25), the ROM controller 230 reads the instruction codes D21 from the ROM 210 and outputs it to the bus 240 as a read data RD (in step S27). This detail is similar to step S15.

Next, a detailed process performed by the CPU 250 when the step S26 is executed will be described with reference to the FIG. 5B. As illustrated in FIG. 5A, if the read address RA matches the replace address RA2, the replacement codes RC2 are output to the bus 240 as the read data RD. The CPU 250 reads its replacement codes RC2 (in step S31).

The CPU 250 jumps to the entry table E1 stored in the ROM 210 by reading the replacement codes RC2 (in step S32). The CPU 250 reads the code included in the entry table E1, reads the entry address of the additional code AC from the jump destination table JT stored in the NVM 220 (in step S33), and then jumps to the additional codes AC indicated by the read entry address (in step S34).

The CPU 250 reads and executes additional codes AC stored in the jump destination (in step S35). When the additional codes AC are executed, a function is added to the instruction codes D21 or a response is made to a fault such as a vulnerability. The CPU 250 jumps to a predetermined position in the ROM 210 by reading the return instruction of the area AC and executes reading of the data to be jumped (in step S36).

For the same reason as the semiconductor device S10 of the first embodiment, even when a defect such as fragility is found in boot ROM cords after shipping of the semiconductor device S20, the CPU 250 can acquire replacement data in place of the data to be replaced. Further, in the semiconductor device S20, as compared with when storing the replacement data in the register, it is possible to increase the code capacitance of the replacement data. Therefore, it is possible to solve the problems (1) and (2).

Further, in the ROM 210 of the semiconductor device S20, the entry table E1 for jumping to the additional coding area of the NVM 220 is stored. The patch area of the NVM 220 stores the replacement codes RC2 for jumping to the entry table E1, and the additional coding area stores the additional codes AC. If the read address RA matches the replace address RA2, the CPU 250 accesses the entry table E1 by referencing the replace codes RC2, accesses the additional codes AC by referencing the entry table E1, and reads the additional codes AC. Thus, by using the entry table E1, the CPU 250 can be jumped anywhere in the NVM 220 simply by the PLC 160 writing a 1-word instruction to the replacement codes RC2.

If the additional codes AC are a high-capacity code, the PLC 160 may not be able to store the additional codes AC in the patch area, and may be forced to store the additional codes AC in the extra coding area, which is the exterior of the patch area. Additional coding areas may be outside of the jumpable areas as seen from the ROM 210. Even in such cases, the entry table E1 can be used to jump the CPU 250 to any location in the additional coding area. Therefore, the semiconductor device S20 is not limited to the patching area, an additional coding area capable of storing a large-capacity code can be used for the storage application of the additional code. Therefore, since a large-capacity additional code can be introduced into the semiconductor device S20, the semiconductor device S20 can accommodate more flexible instruction code modification or the addition of instruction code functionality.

Further, in the second embodiment, it is possible to store all of the data required for replacement in the ROM 210 and the NVM 220, there is no need to provide additional memories. Therefore, it is possible to suppress the number of components of the circuit required for replacement processing. That is, the configuration of the semiconductor device S20, it is possible to suppress the cost of the semiconductor device.

Further, by referring to the entry table E1 stored in the ROM 210, the CPU 250 reads the entry address of the additional codes AC from the jump destination table JT stored in the NVM 220, and then jumps to the additional codes AC indicated by the read entry address. Here, even when different additional codes D21 of different content is required in the plurality of places of the instruction codes D21, by setting the jump destination table AC for each additional codes AC, the CPU 250 can read the additional codes AC corresponding to the part of the instruction codes D21. Therefore, a variety of additional code AC can be flexibly introduced into the semiconductor device S20.

The additional coding area is not connected to the ROM controller 230 and the patching area is connected to the ROM controller 230. Even in such cases, the CPU 250 can obtain additional codes AC stored in a location where the NVM 220 is not connected to the ROM controller 230. Therefore, the configuration of the NVM 220 and the ROM controller 230 can be freely changed, and the flexibility of the circuit configuration of the semiconductor device S20 can be increased.

The present disclosure is not limited to the above embodiment, it is possible to change as appropriate without departing from the scope.

For example, in the semiconductor device S10 in the first embodiment, any type of processor may be used in place of the CPU 150. The ROM controller 130 may be provided with any circuitry capable of performing the processes illustrated in the flow charts above, in place of the AND circuit and the multiplexer. In the semiconductor device S10, for example, at least either the bus 140 or the PLC 160 may not be provided. Variations shown above are similarly applicable to the semiconductor device S20 in the second embodiment.

The semiconductor device described in the above embodiment, for example, a vehicle-mounted camera, a drive recorder, it is possible to mount on a vehicle-mounted electronic device such as a car navigation, the semiconductor device can be mounted device is not limited thereto.

Furthermore, some or all of the processes performed by the ROM controller 130 or the ROM controller 230 may be implemented by having CPU run a computer program.

The program described above includes a set of instructions (or software code) for causing the computer to perform one or more of the functions described in the embodiments when read into the computer. The program may be stored on a non-temporary computer-readable medium or on a tangible storage medium. By way of example and not limitation, computer-readable media or tangible storage media include: RAM (Random-Access Memory), ROM (Read-Only Memory, flash memory, SSD (Solid-State Drive) or other memory techniques, CD-ROM, DVD (Digital Versatile Disc), Blu-ray (registered trademark) disks or other optical disk storage, magnetic cassettes, magnetic tapes, magnetic disk storage or other magnetic storage devices. The program may be transmitted on a temporary computer-readable medium or communication medium. By way of example and not limitation, temporary computer readable media or communication media include electrically, optically, acoustically, or other forms of propagating signals.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a read only memory in which data is stored;
a non-volatile memory in which replacement data for at least part of the data is stored; and
a controller that performs either reading the data from the read only memory or reading the replacement data from the non-volatile memory in response to data read request from a processor.

2. The semiconductor device according to claim 1,
wherein a first address information indicating a storage address of the at least part of the data stored in the read only memory is stored in the non-volatile memory,
wherein the controller reads the replacement data from the non-volatile memory when the address indicated by the data read request is the same as the storage address indicated by the first address information.

3. The semiconductor device according to claim 1 further comprising:
a programmable controller that does not perform writing the replacement data in a first mode, and performs writing of the replacement data in a second mode, with respect to an area where the replacement data is stored in the non-volatile memory.

4. The semiconductor device according to claim 1,
a first jump destination information for jumping to a first area of the non-volatile memory is stored in the read only memory,
a second destination information for jumping to the first jump destination information is stored in a second area of the non-volatile memory,
when the controller reads the replacement data from the non-volatile memory, the processor accesses the first jump destination information by referring to the second jump destination information, and accesses the replacement data by referring to the first jump destination information, and reads the replacement data.

5. The semiconductor device according to claim 4,
wherein a second address information indicating a storage address of the replacement data is stored in the first area,
the processor accesses the second address information by referring to the first jump destination information and reads the replacement data by referring to the second address information.

6. The semiconductor device according to claim 4, wherein the first area is not connected to the controller and the second area is connected to the controller,

7. A method by a semiconductor device having a read only memory in which data is stored and a non-volatile memory in which replacement data for at least part of the data is stored,
the method comprising:
accepting request to read data stored in a read only memory; and
performing either reading the data from the read only memory or reading the replacement data from the non-volatile memory in response to data read request from a processor.

8. The method according to claim 7,
wherein a first address information indicating a storage address of the at least part of the data stored in the read only memory is stored in the non-volatile memory,
wherein the semiconductor device reads the replacement data from the non-volatile memory when the address indicated by the data read request is the same as the storage address indicated by the first address information.

9. The method according to claim 7,
wherein the semiconductor that does not perform writing the replacement data in a first mode, and performs writing of the replacement data in a second mode, with respect to an area where the replacement data is stored in the non-volatile memory.

10. The method according to claim 7,
a first jump destination information for jumping to a first area of the non-volatile memory is stored in the read only memory,
a second destination information for jumping to the first jump destination information is stored in a second area of the non-volatile memory,
when the controller reads the replacement data from the non-volatile memory, the processor accesses the first jump destination information by referring to the second jump destination information, and accesses the replacement data by referring to the first jump destination information, and reads the replacement data.

11. The method according to claim 10,
wherein a second address information indicating a storage address of the replacement data is stored in the first area,
wherein the semiconductor accesses the second address information by referring to the first jump destination information and reads the replacement data by referring to the second address information.

12. A non-transitory memory storing a computer program that is executed by at least one processor, in which the computer program comprising:
codes for accepting request to read data stored in a read only memory; and
codes for performing either reading the data from the read only memory or reading the replacement data from a non-volatile memory in response to data read request.

13. The non-transitory memory according to claim 12,
wherein a first address information indicating a storage address of the at least part of the data stored in the read only memory is stored in the non-volatile memory,
the program further comprising codes for reading the replacement data from the non-volatile memory when the address indicated by the data read request is the same as the storage address indicated by the first address information.
